(19) United States
(12) Patent Application Publication
(10) Pub. No.: US 2018/0292747 A1
(43) Pub. Date: Oct. 11, 2018

(54) PROCESSING APPARATUS OF POLARIZER AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventor: Lixuan CHEN, Shenzhen, Guangdong (CN)

(73) Assignee: Shenzhen China Star Optoelectronics Technology Co., Ltd., Shenzhen, Guangdong (CN)

(21) Appl. No.: 15/526,328

(22) PCT Filed: Mar. 21, 2017
(86) PCT No.: PCT/CN2017/077588

§ 371 Date: May 11, 2017

(30) Foreign Application Priority Data
Jan. 24, 2017 (CN) 201710062186.7

(51) Int. Cl. G03F 7/00; G03F 7/36; C23F 1/00; G03F 7/42; G02B 5/30

(52) U.S. Cl. CPC G03F 7/0002; G03F 7/36; G02B 5/3025; G03F 7/42; G03F 7/0007; C23F 1/00

(57) ABSTRACT

The embodiment of the present application provides a processing apparatus of a polarizer, comprising a drive assembly, a roller imprint template and a stage, and the stage carrying a substrate coated with a photoresist layer, and the roller imprint template being set above the stage, and the drive assembly driving the roller imprint template and the photoresist layer to abut with each other, and the drive assembly driving the roller imprint template to roll from one end of the stage to the other end of the stage to successively imprint a pattern on the photoresist layer. In the processing apparatus of the polarizer according to the present invention, the roller imprint template is used to replace the plane imprint template in prior art to decrease the size of the imprint template, and to reduce the manufacture cost of template, and thus to reduce the manufacture cost of the polarizer.

### CROSS REFERENCE

This application claims the priority of Chinese Patent Application No. 201710062186.7, entitled “Processing apparatus of polarizer and manufacturing method thereof”, filed on Jan. 24, 2017, the disclosure of which is incorporated herein by reference in its entirety.

### FIELD OF THE INVENTION

The present invention relates to a display technology field, and more particularly to a processing apparatus of a polarizer and a manufacturing method thereof.

### BACKGROUND OF THE INVENTION

In prior art, the polarization film can be formed on the glass substrate to construct a polarizer. Specifically, the Nano-imprint Lithography (NIL) or the exposure apparatus can be used to form the polarization film on the glass substrate.

The NIL technology is to form a pattern on the glass substrate with the imprint machine for engraving pattern. The specific process is that after coating the photoresist layer on the glass substrate, the pressure is applied to the plane imprint template to form and print the panel pattern on the photoresist layer. After etching, the desired pattern can be obtained. However, the manufacture of the plane imprint template used in the NIL technology is relatively complicated. The imprint template is generally manufactured by photolithography. Once the size of the imprint template is larger, the manufacture difficulty and the cost will tremendously increase. Therefore, the cost of the polarizer manufactured in the traditional method is high and is desperate to be improved.

### SUMMARY OF THE INVENTION

An objective of the present invention is to provide a processing apparatus of a polarizer, in which using the processing apparatus to manufacture the polarizer can reduce the manufacture cost of the large size polarizer.

Another objective of the present invention is to provide a manufacturing method of a polarizer, in which manufacturing the polarizer with the method can reduce the manufacture cost of the large size polarizer.

For realizing the aforesaid objective, the technical solution provided by the embodiments of the present invention is:

The embodiment of the present application provides a processing apparatus of a polarizer, comprising a drive assembly, a roller imprint template and a stage, and the stage carrying a substrate coated with a photoresist layer, and the roller imprint template being set above the stage, and the drive assembly driving the roller imprint template and the photoresist layer to abut with each other, and the drive assembly driving the roller imprint template to roll from one end of the stage to the other end of the stage to successively imprint a pattern on the photoresist layer.

An angle between a carrying surface of the stage and a horizontal plane is an acute angle, and the one end of the stage is above the other end of the stage in a vertical direction, and the drive assembly drives the roller imprint template to roll in a direction parallel with the carrying surface to successively imprint the pattern on the photoresist layer.

The angle between the carrying surface of the stage and the horizontal plane is α, and 0 degree<α≤15 degrees.

The drive assembly drives the roller imprint template to roll from the one end of the stage to the other end of the stage in a direction parallel with the carrying surface, and the drive assembly further drives the stage with the one end as a shaft and the other end of the stage is rotated around the one end of the stage to make that the one end of the stage is above the other end of the stage in a vertical direction.

An amount of the roller imprint templates is plural, and the plurality of roller imprint templates are arranged side by side in an axial direction thereof, and the drive assembly drives the plurality of roller imprint templates to roll from the one end of the stage to the other end of the stage to successively imprint the pattern on the photoresist layer.

An axial length of the roller imprint template is less than or equal to 100 cm.

The present invention provides a manufacturing method of a polarizer, comprising steps of:

providing a substrate, and fixing the substrate on a carrying surface of a stage;

coating a photoresist layer on one side of the substrate away from the stage;

providing a roller imprint template, and the roller imprint template and the photoresist layer abutting with each other;

rolling the roller imprint template from one end of the stage to the other end of the stage to successively imprint a pattern on the photoresist layer;

curing the photoresist layer.

The step of curing the photoresist layer comprises irradiating UV light on a bottom of the substrate to cure the photoresist layer.

The substrate comprises a transparent substrate and a metal layer which are stacked up, and the photoresist layer is coated on the metal layer; after curing the photoresist layer, the manufacturing method further comprises:

etching the metal layer through the photoresist layer to form a metal wire grid pattern on the metal layer;

removing the photoresist layer.

A dry etching method is used to etch the photoresist layer and the metal layer to form the metal wire grid pattern on the metal layer.

The embodiments of the present invention have advantages or benefits:

The processing apparatus of the polarizer according to the present invention comprises a drive assembly, a roller imprint template and a stage, and the stage carrying a substrate coated with a photoresist layer, and the roller imprint template being set above the stage, and the drive assembly driving the roller imprint template and the photoresist layer to abut with each other, and the drive assembly driving the roller imprint template to roll from one end of the stage to the other end of the stage to successively imprint a pattern on the photoresist layer. In the processing apparatus of the polarizer according to the present invention, the roller imprint template is used to replace the plane imprint template in prior art to decrease the size of the imprint template, and to reduce the manufacture cost of imprint template, and thus to reduce the manufacture cost of the polarizer. The manufacturing method of the polarizer according to the present invention can reduce the manufacture cost of the polarizer.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structure diagram of a processing apparatus of a polarizer provided by one embodiment of the present invention.

FIG. 2 is a simple structure diagram of a processing apparatus of a polarizer provided by another embodiment of the present invention.

FIG. 3 is a flowchart diagram of a manufacturing method of a polarizer according to the present invention.

FIG. 4 is a structure diagram of a photoresist layer on the substrate after imprinting.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

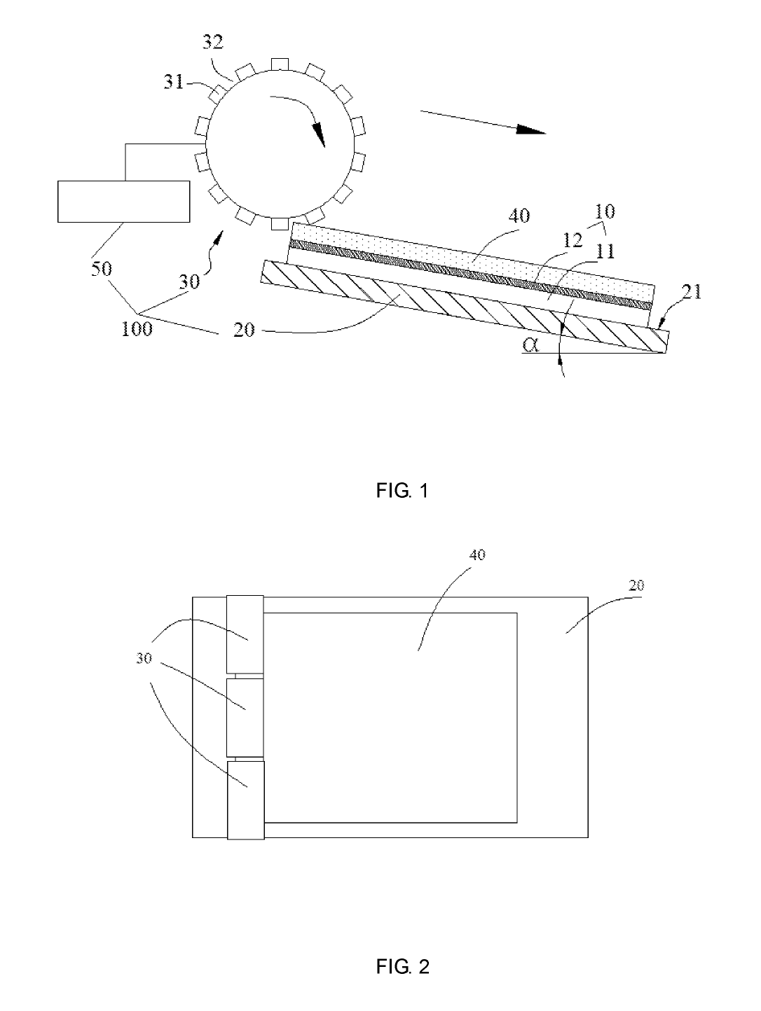

Please refer to FIG. 1. FIG. 1 is a structure diagram of a processing apparatus of a polarizer provided by one embodiment of the present invention. The processing apparatus 100 of the polarizer of this embodiment comprises a drive assembly 50, a roller imprint template 30 and a stage 20, and the stage 20 carrying a substrate 10 coated with a photoresist layer 40, and the roller imprint template 30 being set above the stage 20, and the drive assembly 50 driving the roller imprint template 30 and the photoresist layer 40 to abut with each other, and the drive assembly 50 driving the roller imprint template 30 to roll from one end of the stage 20 to the other end of the stage to successively imprint a pattern on the photoresist layer 40.

In the processing apparatus of the polarizer according to the present invention, the roller imprint template is used to replace the plane imprint template in prior art to decrease the size of the imprint template, and to reduce the manufacture cost of imprint template, and thus to reduce the manufacture cost of the polarizer.

Specifically, the roller imprint template 30 has a substantially cylindrical shape. A plurality of strip protrusions 31 are distributed on an outer peripheral surface of the roller imprint template 30. The plurality of strip projections 31 are arranged in parallel, and the adjacent stripe protrusions 31 are spaced apart by a groove 32, and the strip projections 31 extend in an axial direction of the roller. Furthermore, an axial length of the roller imprint template 30 is specifically less than or equal to 100 cm. Usually speaking, the acting force of the drive assembly 50 applied to the roller imprint template 30 is close to the positions of the two ends of the roller imprint template 30. Therefore, the pressure at both ends of the roller imprint template 30 is larger than the pressure at the middle. The longer the length of the roller imprint template 30 is, the larger the difference of the pressure at the two ends and the pressure at the middle becomes. When the difference of the pressure at the two ends and the pressure at the middle is larger, the depths of imprinting a pattern on the photoresist layer 40 with the roller imprint template 30 are different to result in the yield decrease of the polarizers. Besides, the over large difference of the pressures is also disadvantageous for maintaining the rigidity of the roller imprint template 30 to lead to the deformation of the roller imprint template 30 and to shorten the service lifetime. Moreover, considering that the size of the processing apparatus 100 cannot be too large, it has to ensure that the diameter of the roller imprint template 30 is not larger than 80 cm.

In one possible embodiment of the present invention, an amount of the roller imprint templates 30 can be plural. Please refer to FIG. 2. FIG. 2 is a simple structure diagram of a processing apparatus of a polarizer provided by another embodiment of the present invention. The plurality of roller imprint templates 30 are arranged side by side in an axial direction thereof, and the drive assembly 50 drives the plurality of roller imprint templates 30 to roll from the one end of the stage 20 to the other end of the stage 20 to successively imprint the pattern on the photoresist layer 40. It can be understood that with the plurality of roller imprint templates 30 arranged side by side, the large scale of substrate 10 can be imprinted and formed in one time, and thus to generate the polarizer of larger size. Specifically, the area corresponding to the junctions on the polarizer with two roller imprint templates 30 can be designed to be a light shielding areas. The black matrix or metal lines are correspondingly arranged at the light shielding areas for shielding the light.

In one possible embodiment of the present invention, the carrying surface 21 of the stage 20 can be a slope. One end of the stage 20 is above the other end of the stage 20 in a vertical direction. Namely, one end of the stage 20 is higher than the other end of the stage 20. the drive assembly 50 drives the roller imprint templates 30 to possess the componental movement in the vertical direction to ensure that the roller imprint templates 30 constantly rolls in a direction parallel with the carrying surface 21, and the roller imprint templates 30 contacts with the photoresist layer 40, and thus to successively imprint a pattern on the photoresist layer 40. The objective of arranging the carrying surface 21 to be a slope is that in general, the acting force of the drive assembly 50 applied to the roller imprint template 30 in the processing apparatus 100 is close to the positions of the two ends of the roller imprint template 30, the positive pressure applied to where the photoresist layer 40 contacts with the two ends of the roller imprint template 30 is larger than the positive pressure applied to the middle of the roller imprint template 30. By arranging the carrying surface 21 to be a slope, the positive pressure difference of the positive pressure between the photoresist layer 40 and the two ends of the roller imprint template 30 and the positive pressure of the middle of the photoresist layer 40 and the roller imprint template 30 can be decreased. Namely, the acted forces at the respective positions on the photoresist layer 40 in the imprinting process can be more even, and thus the depths of imprinting the pattern on the photoresist layer 40 with the roller imprint template 30 are more even to promote the yield of the polarizers.

Preferably, the angle (i.e. the tilt angle) between the carrying surface 21 and the horizontal plane is α, wherein 0 degree<α≤15 degrees. It can be understood that the larger the tilt angle αis, the running distance of the roller imprint templates 30 in the vertical direction is larger, and the volume of the corresponding processing apparatus 100 is also larger. Experiments show that once the tilt angle α is within 15 degrees, the volume of the processing apparatus 100 is in the proper range. Preferably, 6 degrees<α≤10 degrees. In one specific embodiment of the present invention, the tilt angle α can be 15 degrees.

In another possible embodiment of the present invention, the stage 20 also can be a stage 20 rotating in the vertical direction. Specifically, the drive assembly 50 further drives the stage 20 with the one end as a shaft and the other end of the stage 20 is rotated around the one end of the stage 20. In the initial status, the angle of the carrying plane and the horizontal plane is 0 degree. In the imprinting process, the drive assembly 50 drives the stage 20 to rotate at a certain angular velocity to make one end of the stage 20 higher than the other end of the stage. The movement direction of the roller imprint template 30 constantly maintains to be parallel with the carrying surface 21. Namely, the roller imprint templates 30 possesses the componental movement in the vertical direction to ensure that the roller imprint templates 30 constantly contacts with the photoresist layer 40, and thus to successively imprint the pattern on the photoresist layer 40. Similar with the aforesaid embodiment, by arranging the stage 20 to be able to rotate in the vertical direction, the positive pressure difference of the positive pressure between the photoresist layer 40 and the two ends of the roller imprint template 30 and the positive pressure of the middle of the photoresist layer 40 and the roller imprint template 30 can be decreased. Namely, the acted forces at the respective positions on the photoresist layer 40 in the imprinting process can be more even, and thus the depths of imprinting the pattern on the photoresist layer 40 with the roller imprint template 30 are more even to promote the yield of the polarizers. Furthermore, the rotating angle of the carrying surface 21 is α, wherein 0 degree<α≤15 degrees. Preferably, 6 degrees<α≤10 degrees. In one specific embodiment of the present invention, the tilt angle αcan be 15 degrees.

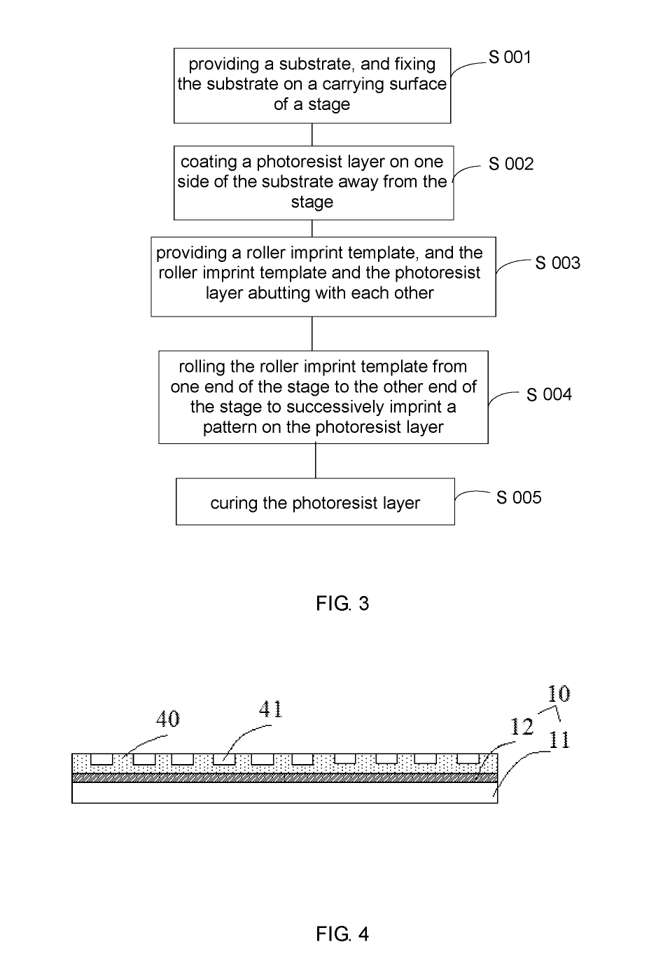

Please refer to FIG. 3. FIG. 3 is a flowchart diagram of a manufacturing method of a polarizer according to the present invention. The manufacturing method of the polarizer according to one embodiment of the present invention mainly comprises steps of:

step S001: providing a substrate, and fixing the substrate on a carrying surface of a stage;

Please refer to FIG. 1 and FIG. 2. Specifically, the substrate 10 comprises a transparent substrate 11 and a metal layer 12 which are stacked up. The surface of the transparent substrate 11 should have the better smoothness. Specifically, the material of the transparent substrate 11 can be a hard substrate, such as a silicon wafer or a glass plate. In this embodiment, the material of the transparent substrate 11 is a silicon wafer. The metal layer 12 can be deposited by the well known technology in this field. For instance, the heat evaporation, the electron beam evaporation and the sputtering coating can be illustrated. In this embodiment, the material of the metal layer 12 is aluminum. Otherwise, other reflective metal also can be used, such as gold, silver, copper, nickel and any alloy of the aforesaid metals. The thickness of the metal layer 12 can be with a range of 10 to 1000 nanometers, and preferably with a range of 100 to 200 nanometers.

step S002: coating a photoresist layer on one side of the substrate away from the stage 20.

It can be understood that the transparent substrate 11 is located on the carrying surface 21 of the stage 20, and the photoresist layer 40 is coated on the metal layer 12 and completely the metal layer 12. Preferably, the thickness of the photoresist layer 40 is between 50 nanometers to 5 micrometers. The photoresist layer 40 can be positive photoresist or negative photoresist. In this embodiment, the thickness of the photoresist layer 40 is 2.5 micrometers. The photoresist layer 40 preferably is SU8, which can form the sturdy mechanical features, and can be well adhered to the surface of the silicon wafer.

It can be understood that step S001 and step S002 can be exchanged. Namely, the photoresist layer 40 can be first coated on the substrate 10, and then the substrate 10 is located on the stage 20.

step S003: providing a roller imprint template, and a plurality of strip protrusions are distributed on an outer peripheral surface of the roller imprint template, and the roller imprint template and the photoresist layer abut with each other.

It can be understood that as the imprint to the photoresist layer 40 starts, the roller imprint template 30 and the photoresist layer 40 should abut with each other.

step S004: rolling the roller imprint template from one end of the stage to the other end of the stage to successively imprint a pattern on the photoresist layer.

It can be understood that the roller imprint template 30 constantly contact with the photoresist layer 40 in the entire imprinting process. The roller imprint template 30 is imprinted on the photoresist layer 40 to form a pattern on the photoresist layer 40. The strip protrusions 31 correspondingly form grooves 41 on the photoresist layer 40. Specifically, refer to FIG. 4. In one possible embodiment of the present invention, the roller imprint template 30 is imprinted on the photoresist layer 40 to form a plurality of strip grooves in parallel on the photoresist layer 40. The roller imprint template 30 is moved from one end of the stage 20 to the other end of the stage 20 to imprint the successive pattern on the entire surface of the photoresist layer 40.

It can be understood that the transparent substrate 11 can be adhered on the carrying surface 21 of the stage 20. The roller imprint template 30 rolls in a direction parallel with the carrying surface 21 in the imprinting process to the photoresist layer 40.

step S005: curing the photoresist layer.

It can be understood that after forming the pattern (grooves 41) on the photoresist layer 40, it is also required the curing treatment. Specifically, the UV light can be used to irradiate on the photoresist layer 40. For instance, the UV lamp can be fixed on the stage 20 to irradiate the UV light on a bottom of the substrate 10 to cure the photoresist layer 40. In other embodiments, the UV light can directly irradiate on the photoresist layer 40 for curing, and no restriction is claimed here.

At this point, the patterning of the photoresist layer 40 is accomplished.

For the polarizer, the manufacturing method further comprises steps of:

step S0051: etching the metal layer through the photoresist layer to form a metal wire grid pattern on the metal layer.

Specifically, a dry etching method or a wet etching method can be used to etch the photoresist layer 40. In one specific embodiment of the present invention, a dry etching method is used to etch the photoresist layer 40, and thus to etch the metal layer 12 under the groove of the photoresist layer 40. Accordingly, the metal wire grid pattern similar with the photoresist layer 40 is also formed on the metal layer 12.

step S0052: removing the photoresist layer.

Specifically, a method of ashing removing, mechanical removing or acid removing can be used to remove the photoresist layer 40 from the substrate 10.

In the description of the present specification, the reference terms, “one embodiment”, “some embodiments”, “an illustrative embodiment”, “an example”, “a specific example”, or “some examples” mean that such description combined with the specific features of the described embodiments or examples, structure, material, or characteristic is included in the utility model of at least one embodiment or example. In the present specification, the terms of the above schematic representation do not certainly refer to the same embodiment or example. Meanwhile, the particular features, structures, materials, or characteristics which are described may be combined in a suitable manner in any one or more embodiments or examples.

Above are embodiments of the present invention, which does not limit the scope of the present invention. Any modifications, equivalent replacements or improvements within the spirit and principles of the embodiment described above should be covered by the protected scope of the invention.

What is claimed is:

1. A processing apparatus of a polarizer, comprising a drive assembly, a roller imprint template and a stage, and the stage carrying a substrate coated with a photoresist layer, and the roller imprint template being set above the stage, and the drive assembly driving the roller imprint template and the photoresist layer to abut with each other, and the drive assembly driving the roller imprint template to roll from one end of the stage to the other end of the stage to successively imprint a pattern on the photoresist layer.

2. The processing apparatus of the polarizer according to claim 1, wherein an angle between a carrying surface of the stage and a horizontal plane is an acute angle, and the one end of the stage is above the other end of the stage in a vertical direction, and the drive assembly drives the roller imprint template to roll in a direction parallel with the carrying surface to successively imprint the pattern on the photoresist layer.

3. The processing apparatus of the polarizer according to claim 2, wherein the angle between the carrying surface of the stage and the horizontal plane is α, and 0 degree<α≤15 degrees.

4. The processing apparatus of the polarizer according to claim 1, wherein the drive assembly drives the roller imprint template to roll from the one end of the stage to the other end of the stage in a direction parallel with the carrying surface, and the drive assembly further drives the stage with the one end as a shaft and the other end of the stage is rotated around the one end of the stage to make that the one end of the stage is above the other end of the stage in a vertical direction.

5. The processing apparatus of the polarizer according to claim 1, wherein an amount of the roller imprint templates is plural, and the plurality of roller imprint templates are arranged side by side in an axial direction thereof, and the drive assembly drives the plurality of roller imprint templates to roll from the one end of the stage to the other end of the stage to successively imprint the pattern on the photoresist layer.

6. The processing apparatus of the polarizer according to claim 1, wherein an axial length of the roller imprint template is less than or equal to 100 cm.

7. A manufacturing method of a polarizer, comprising steps of:
providing a substrate, and fixing the substrate on a carrying surface of a stage;
coating a photoresist layer on one side of the substrate away from the stage;
providing a roller imprint template, and the roller imprint template and the photoresist layer abutting with each other;
rolling the roller imprint template from one end of the stage to the other end of the stage to successively imprint a pattern on the photoresist layer;
curing the photoresist layer.

8. The manufacturing method of the polarizer according to claim 7, wherein the step of curing the photoresist layer comprises irradiating UV light on a bottom of the substrate to cure the photoresist layer.

9. The manufacturing method of the polarizer according to claim 7, wherein the substrate comprises a transparent substrate and a metal layer which are stacked up, and the photoresist layer is coated on the metal layer; after curing the photoresist layer, the manufacturing method further comprises:
etching the metal layer through the photoresist layer to form a metal wire grid pattern on the metal layer;
removing the photoresist layer.

10. The manufacturing method of the polarizer according to claim 7, wherein a dry etching method is used to etch the photoresist layer and the metal layer to form the metal wire grid pattern on the metal layer.
